(19) United States
(12) Patent Application Publication
(10) Pub. No.: US 2019/0390347 A1
(43) Pub. Date: Dec. 26, 2019

(54) CONTROL DEVICE, FILM FORMING APPARATUS, CONTROL METHOD, FILM FORMING METHOD, AND RECORDING MEDIUM

(71) Applicant: TOKYO ELECTRON LIMITED, Tokyo (JP)

(72) Inventors: Tatsuya YAMAGUCHI, Nirasaki City (JP); Syuji NOZAWA, Nirasaki City (JP); Makoto FUJIKAWA, Nirasaki City (JP)

(21) Appl. No.: 16/446,019

(22) Filed: Jun. 19, 2019

(30) Foreign Application Priority Data
Jun. 21, 2018 (JP) 2018-117920

(51) Int. Cl. C23C 16/52

(52) U.S. Cl. CPC C23C 16/52

(57) ABSTRACT

There is provided a control device, comprising: an acquisition part configured to acquire data of saturation vapor pressure curves for plural types of raw materials used to form a film on a workpiece, and a predetermined saturation vapor pressure value set for the workpiece; a selection part configured to select a raw material having a lowest saturation vapor pressure at a certain temperature, among the plural types of raw materials, based on the data of the saturation vapor pressure curves; a calculation part configured to calculate a temperature corresponding to the predetermined saturation vapor pressure value for the selected raw material based on the data of the saturation vapor pressure curve for the selected raw material; and a controller configured to control a temperature of the workpiece to the calculated temperature.

### CROSS-REFERENCE TO RELATED APPLICATION

This application is based upon and claims the benefit of priority from Japanese Patent Application No. 2018-117920, filed on Jun. 21, 2018, the entire contents of which are incorporated herein by reference.

### TECHNICAL FIELD

The present disclosure relates to a control device, a film forming apparatus, a control method, a film forming method, and a non-transitory computer-readable recording medium.

### BACKGROUND

Patent Document 1 discloses a method of producing a polyurea film by vacuum vapor deposition polymerization of an aromatic alkyl, alicyclic or aliphatic diisocyanate monomer, and an aromatic alkyl, alicyclic or aliphatic diamine monomer. In Patent Document 1, the diisocyanate monomer and the diamine monomer having a difference of 10 kJ or less in activation energy required for desorption from a base material are used. According to the technique disclosed in Patent Document 1, there is provided a method of forming a polyurea film that is excellent in transparency, light resistance and mass productivity.

### RELATED ART DOCUMENTS

### Patent Documents

Patent Document 1: WO 2008/129925

### SUMMARY

Some embodiments of the present disclosure provide techniques capable of easily controlling formation of a film from plural types of raw materials.

According to an embodiment of the present disclosure, there is provided a control device, including: an acquisition part configured to acquire data of saturation vapor pressure curves for plural types of raw materials used to form a film on a workpiece, and a predetermined saturation vapor pressure value set for the workpiece; a selection part configured to select a raw material having a lowest saturation vapor pressure at a certain temperature, among the plural types of raw materials, based on the data of the saturation vapor pressure curves; a calculation part configured to calculate a temperature corresponding to the predetermined saturation vapor pressure value for the selected raw material based on the data of the saturation vapor pressure curve for the selected raw material; and a controller configured to control a temperature of the workpiece to the calculated temperature.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of a configuration of a film forming apparatus according to an embodiment of the present disclosure.

FIG. 2 is a diagram illustrating an example of a control method according to an embodiment of the present disclosure.

FIG. 3 is a block diagram illustrating an example of a configuration of a control device according to an embodiment of the present disclosure.

FIG. 4 is a diagram illustrating an example of saturation vapor pressure curve data included in the control device according to an embodiment of the present disclosure.

FIG. 5 is a diagram illustrating an example of saturation vapor pressure set values included in the control device according to an embodiment of the present disclosure.

FIG. 6 is a diagram illustrating an example of an operation of a selection part included in the control device according to an embodiment of the present disclosure.

FIG. 7 is a diagram illustrating an example of an operation of a calculation part included in the control device according to an embodiment of the present disclosure.

FIG. 8 is a flowchart illustrating an example of a processing sequence of the control method according to an embodiment of the present disclosure.

FIG. 9 is a flowchart illustrating an example of a processing sequence of a film forming method according to an embodiment of the present disclosure.

FIG. 10 is a block diagram illustrating an example of a configuration of a control device according to a modification of the embodiment of the present disclosure.

FIG. 11 is a flowchart illustrating an example of a processing sequence of a control method according to a modification of the embodiment of the present disclosure.

FIG. 12 is a diagram illustrating a first example of the control method according to the embodiment of the present disclosure.

FIG. 13 is a diagram illustrating a second example of the control method according to an embodiment of the present disclosure.

FIG. 14 is a diagram illustrating a third example of the control method according to an embodiment of the present disclosure.

FIG. 15 is a hardware configuration diagram illustrating an example of a computer that realizes the function of the control device.

### DETAILED DESCRIPTION

Embodiments of a control device, a film forming apparatus, a control method, a film forming method, and a non-transitory computer-readable recording medium according to the present disclosure will now be described in detail with reference to the drawings. Further, the present disclosure is not limited by the embodiments described below. In addition, it should be noted that the drawings are schematic, and the relationships between the dimensions of respective elements, the ratios of the respective elements, and the like may differ from reality. Also, there may be a case where the relationships of dimensions and ratios differ from each other between the drawings.

### <Film Forming Apparatus>

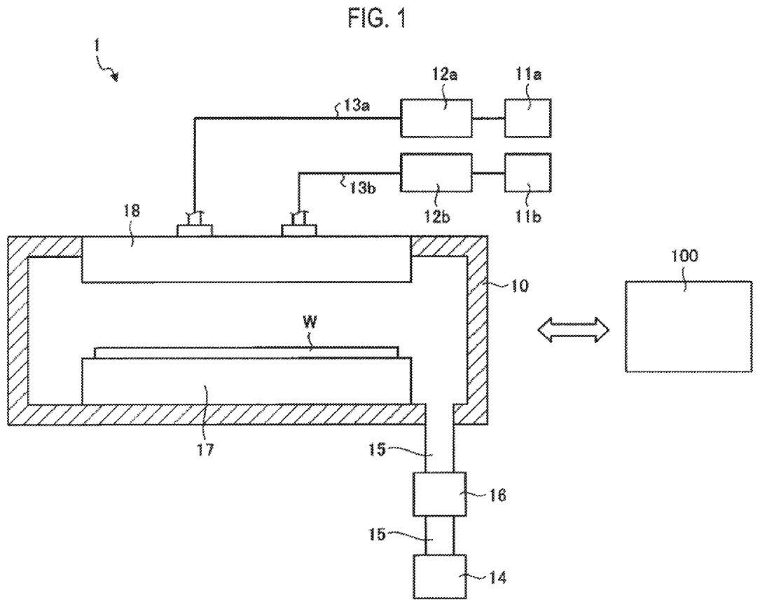

First, an example of a configuration of a film forming apparatus 1 according to an embodiment of the present disclosure will be described with reference to FIG. 1. FIG. 1 is a cross-sectional view illustrating an example of the configuration of the film forming apparatus 1 according to an embodiment of the present disclosure. The film forming apparatus 1 is an apparatus that forms a film on a workpiece W. For example, the film forming apparatus 1 is a chemical vacuum deposition (CVD) apparatus. The workpiece W is, for example, a wafer which is a substrate of a semiconductor device.

In the following description, a case where plural types of raw materials used to form a film on the workpiece W are two types of raw materials, for example, a raw material A as a first raw material and a raw material B as a second raw material, will be described. For example, in a case where a polyurea film is formed on the workpiece W, examples of the raw material A and the raw material B may include diisocyanate and diamine, respectively. In the film forming apparatus 1, the polyurea film is formed on a front surface of the workpiece W by subjecting the diisocyanate and the diamine to a vapor deposition polymerization on the front surface of the workpiece W.

The film forming apparatus 1 includes a chamber 10, a first raw material source 11a, a second raw material source 11b, a first vaporizer 12a, a second vaporizer 12b, a first supply pipe 13a, a second supply pipe 13b, an exhaust device 14, an exhaust pipe 15, and a collection device 16.

The chamber 10 is a vacuum container having an inner wall by which a vacuum atmosphere is defined. The vacuum atmosphere used herein may be a medium vacuum state (100 to 0.1 Pa). The workpiece W is carried into the chamber 10. The chamber 10 includes a mechanism that adjusts a temperature of the vacuum atmosphere inside the chamber 10. For example, the chamber 10 includes a heater that heats the inner wall of the chamber 10.

The first raw material source 11a stores a liquid of the raw material A as the first raw material. The first raw material source 11a supplies the raw material A staying in a liquid state to the first vaporizer 12a.

The second raw material source 11b stores a liquid of the raw material B as the second raw material. The second raw material source 11b supplies the raw material B staying in a liquid state to the second vaporizer 12b.

The first vaporizer 12a vaporizes the liquid of the raw material A supplied from the first raw material source 11a. The first vaporizer 12a may include a heater that heats the liquid of the raw material A supplied from the first raw material source 11a.

The second vaporizer 12b vaporizes the liquid of the raw material B supplied from the second raw material source 11b. The second vaporizer 12b may include a heater that heats the liquid of the raw material B supplied from the second raw material source 11b.

The first raw material source 11a and the first vaporizer 12a are coupled to the chamber 10 through the first supply pipe 13a. The first supply pipe 13a supplies a gas of the raw material A generated by the first vaporizer 12a to the chamber 10. The first supply pipe 13a includes a mechanism that adjusts a temperature of the gas of the raw material A flowing through the first supply pipe 13a, for example, a heater that heats the first supply pipe 13a.

The second raw material source 11b and the second vaporizer 12b are coupled to the chamber 10 through the second supply pipe 13b. The second supply pipe 13b supplies a gas of the raw material B generated by the second vaporizer 12b to the chamber 10. The first supply pipe 13a includes a mechanism that adjusts a temperature of the gas of the raw material B flowing through the second supply pipe 13b, for example, a heater that heats the second supply pipe 13b.

The exhaust device 14 exhausts the interior of the chamber 10 so as to form a vacuum atmosphere inside the chamber 10. The exhaust device 14 includes a vacuum pump for exhausting the interior of the chamber 10 and a vacuum gauge for measuring an internal pressure of the chamber 10.

The exhaust device 14 is coupled to the chamber 10 through the exhaust pipe 15. The exhaust pipe 15 exhausts, for example, non-reacted gas of the raw material A and non-reacted gas of the raw material B, which have been supplied into the chamber 10 but not been used to form a film on the workpiece W. Furthermore, the exhaust pipe 15 exhausts, for example, particles generated inside the chamber 10. Examples of the particles generated inside the chamber 10 may include reaction products of the raw material A and the raw material B which have been supplied into the chamber 10 but not been used to form a film on the workpiece W.

The collection device 16 collects the particles generated inside the chamber 10. The collection device 16 includes a member made of a material having the function of collecting the particles generated inside the chamber 10 (hereinafter, referred to as a “particle collection function member”). For example, the collection device 16 includes a mesh-like member such as a metallic mesh or the like. The collection device 16 includes a mechanism that adjusts a temperature of the particle collection function member, for example, a mechanism that cools down the particle collection function member by water cooling or the like. The collection device 16 is provided in the exhaust pipe 15 between the chamber 10 and the exhaust device 14.

The chamber 10 includes a stage 17 and a shower head 18.

The stage 17 mounts the workpiece W carried into the chamber 10 thereon. For example, the stage 17 is provided in a lower portion of the chamber 10. The stage 17 includes a mechanism that adjusts a temperature of the workpiece W mounted on the stage 17, for example, a heater that heats the workpiece W mounted on the stage 17.

The shower head 18 discharges the gas of the raw material A supplied through the first supply pipe 13a and the gas of the raw material B supplied through the second supply pipe 13b into the chamber 10. For example, the shower head 18 is provided in an upper portion of the chamber 10. In a lower surface of the shower head 18, there are formed a first discharge hole through which the gas of the raw material A supplied through the first supply pipe 13a is discharged into the chamber 10, and a second discharge hole through which the gas of the raw material B supplied through the second supply pipe 13b is discharged into the chamber 10.

The film forming apparatus 1 causes the raw material A and the raw material B to react with each other on the front surface of the workpiece W by supplying the gas of the raw material A and the gas of the raw material B onto the workpiece W mounted on the stage 17 in a state where the interior of the chamber 10 is kept in a vacuum atmosphere. As a result, the film forming apparatus 1 forms a film on the front surface of the workpiece W.

The film forming apparatus 1 further includes a control device 100. The control device 100 controls the temperature of the workpiece W. In some embodiments, the control device 100 may further control at least one of a temperature of the chamber 10, a temperature of the exhaust pipe 15, and a temperature of the collection device 16. The control device 100 is connected to parts other than the control device 100 in the film forming apparatus 1 in a wired or wireless manner. An example of a configuration of the control device 100 will be described later.

### <Control Method>

In the related art, when a film is formed on the workpiece W, a flow rate of each of the raw material A and the raw material B supplied into the chamber 10 is controlled with high accuracy so that a difference between a vapor pressure (partial pressure) of the raw material A and a vapor pressure (partial pressure) of the raw material B inside the chamber 10 is reduced. However, since the flow rate of each of the raw material A and the raw material B is controlled with high accuracy, the formation of a film from the raw material A and the raw material B could not be easily controlled. The present embodiment provides a technique capable of easily controlling the formation of a film from the raw material A and the raw material B.

In the film forming apparatus 1, a rate at which a film is formed on the workpiece W by using the material A and the material B (hereinafter, referred to as a “film-forming rate”) depends on the types of the material A and the material B used to form the film, the temperature of the workpiece W, and the like. In the present embodiment, the temperature of the workpiece W is controlled based on a saturation vapor pressure curve of the raw material A which has a relatively low saturation vapor pressure at a certain temperature, among the raw material A and the raw material B. Specifically, the temperature of the workpiece W is controlled to a temperature corresponding to a predetermined saturation vapor pressure value for the saturation vapor pressure curve of the raw material A.

In the present embodiment, it has been found that, even when the temperature of the workpiece W is controlled based on the saturation vapor pressure curve of the raw material A among the raw material A and the raw material B, a film can be formed on the workpiece W at a certain range of film-forming rate. An example of the certain range of film-forming rate may include 1 to 1,000 nm/min. In the present embodiment, the flow rate of the raw material A is controlled so that the vapor pressure (partial pressure) of the raw material A is equal to a predetermined saturation vapor pressure. On the other hand, in the present embodiment, the tolerance of the flow rate of the raw material B having a relatively high saturation vapor pressure at a certain temperature can be increased. Thus, in the present embodiment, it is possible to easily control the formation of a film from the raw material A and the raw material B.

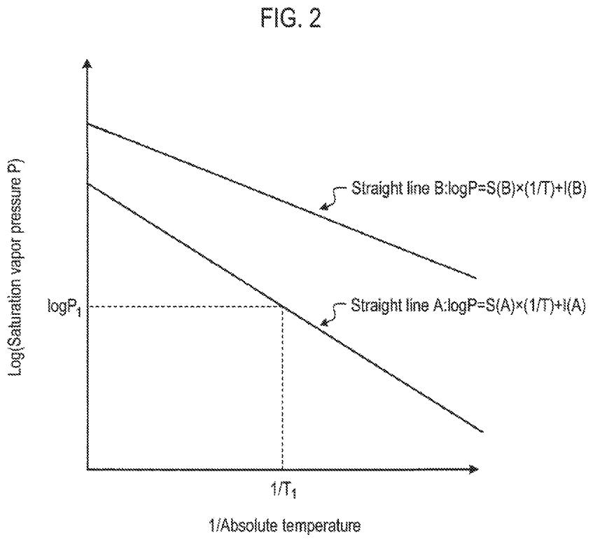

Next, an example of a control method according to an embodiment of the present disclosure will be described with reference to FIG. 2. FIG. 2 is a diagram illustrating an example of the control method according to an embodiment of the present disclosure. The control method according to an embodiment of the present disclosure is carried out by the control device 100 included in the film forming apparatus 1.

FIG. 2 illustrates a saturation vapor pressure curve of the raw material A and a saturation vapor pressure curve of the raw material B. In FIG. 2, the horizontal axis and the vertical axis indicate a reciprocal of an absolute temperature T of the workpiece W and a logarithm of a saturation vapor pressure P of the raw material A or the raw material B, respectively. In FIG. 2, the saturation vapor pressure curve of the raw material A or the raw material B is indicated by a logarithm log P of the saturation vapor pressure P of the raw material A or the raw material B and a reciprocal (1/T) of the absolute temperature T of the workpiece W. The logarithm log P of the saturation vapor pressure P of the raw material A or the raw material B and the reciprocal (1/T) of the absolute temperature T of the workpiece W are in a substantially linear relationship with each other.

In FIG. 2, the saturation vapor pressure curve of the raw material A is approximated by a straight line A indicated by log P=S(A)×(1/T)+I(A). S(A) and I(A) are respectively a slope and an intercept of the straight line A. The saturation vapor pressure curve of the raw material B is approximated by a straight line B indicated by log P=S(B)×(1/T)+I(B). S(B) and I(B) are respectively a slope and an intercept of the straight line B. As illustrated in FIG. 2, the raw material A is a raw material having a relatively low saturation vapor pressure at a certain temperature. The raw material B is a raw material having a relatively high saturation vapor pressure at a certain temperature.

A predetermined saturation vapor pressure value P₁ illustrated in FIG. 2 is a predetermined saturation vapor pressure value set for the workpiece W to form a film on the workpiece W. A temperature T₁ illustrated in FIG. 2 is an absolute temperature of the workpiece W, which corresponds to the predetermined saturation vapor pressure value P₁ for the raw material A which is a raw material having a relatively low saturation vapor pressure at a certain temperature.

The control device 100 acquires S(A) and I(A) as data of the saturation vapor pressure curve for the raw material A, S(B) and I(B) as data of the saturation vapor pressure curve for the raw material B, and the predetermined saturation vapor pressure value P₁ set for the workpiece W.

The control device 100 selects the raw material A which is a raw material having a relatively low saturation vapor pressure at a certain temperature, among the raw material A and the raw material B, based on S(A), I(A), S(B), and I(B).

The control device 100 calculates the temperature T₁ corresponding to the predetermined saturation vapor pressure value P₁ for the selected raw material A based on the data S(A) and I(A) of the saturation vapor pressure curve for the selected raw material A.

The control device 100 controls the heater or the like provided in the stage 17 so that the temperature of the workpiece W is equal to the calculated temperature T₁. In this manner, the control device 100 controls so that the temperature of the workpiece W is equal to the temperature T₁ corresponding to the predetermined saturation vapor pressure value P₁ for the raw material A based on the saturation vapor pressure curve of the raw material A which is a raw material having a relatively low saturation vapor pressure at a certain temperature, among the raw material A and the raw material B.

### <Control Device>

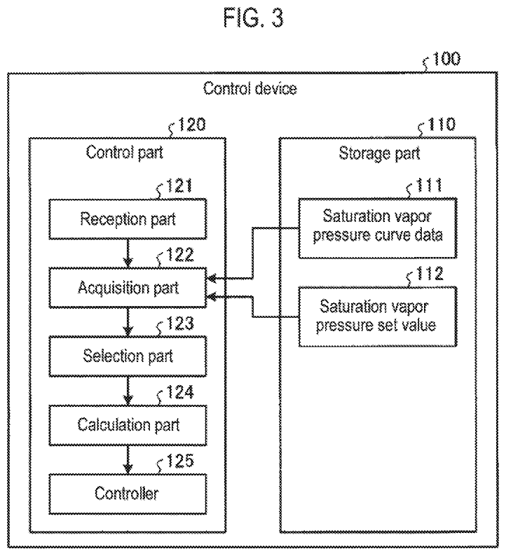

Next, an example of a configuration of the control device 100 according to an embodiment of the present disclosure will be described with reference to FIG. 3. FIG. 3 is a block diagram illustrating an example of the configuration of the control device 100 according to an embodiment of the present disclosure. The control device 100 is, for example, a computer.

The control device 100 includes a storage part 110 and a control part 120.

The storage part 110 is realized by, for example, a semiconductor memory device such as a random access memory (RAM) or a flash memory, or a storage device such as a hard disk or an optical disc. The storage part 110 stores data such as a saturation vapor pressure curve data 111 and a saturation vapor pressure set value 112.

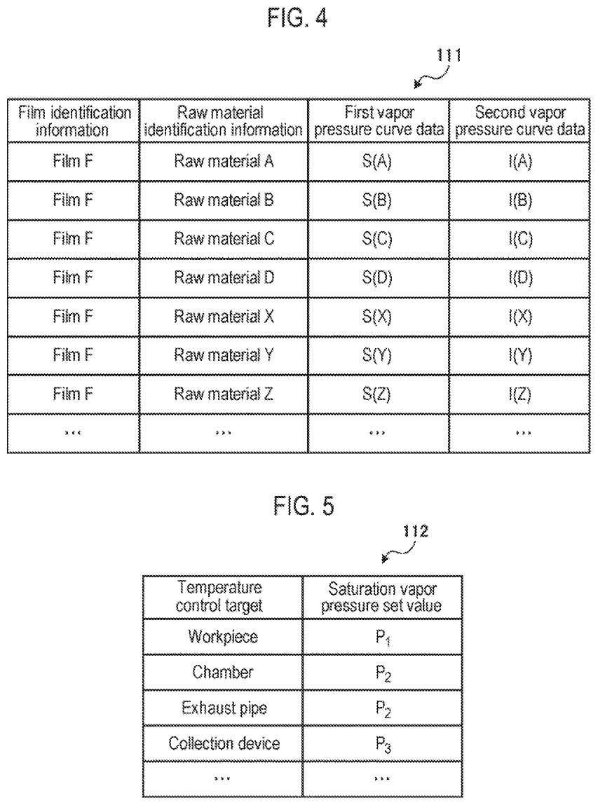

The saturation vapor pressure curve data 111 is the data of the saturation vapor pressure curves for plural types of raw materials used to form a film on the workpiece W. An example of the saturation vapor pressure curve data 111 included in the control device 100 according to an embodiment of the present disclosure will be described with reference to FIG. 4. FIG. 4 is a diagram illustrating an example of the saturation vapor pressure curve data 111 included in the control device 100 according to an embodiment of the present disclosure.

In the example illustrated in FIG. 4, the saturation vapor pressure curve data 111 includes items such as a “film identification information”, a “raw material identification information”, a “first vapor pressure curve data”, and a “second vapor pressure curve data”. In the saturation vapor pressure curve data 111, the information stored in the items of the “film identification information”, the “raw material identification information”, the “first vapor pressure curve data”, and the “second vapor pressure curve data” are associated with one another.

The “film identification information” is an identification information for identifying a film formed on the workpiece W. In the example illustrated in FIG. 4, for example, information such as a “film F” is stored in the “film identification information” item. The information such as the “film F” is not particularly limited as long as it can identify the film formed on the workpiece W. As an example, information on the type of a film such as polyurea or polyimide. The information such as the “film F” may be, for example, a symbol or a number indicating a film determined by a user.

The “raw material identification information” is an identification information for identifying raw materials used to form a film on the workpiece W. In the example illustrated in FIG. 4, for example, information such as “raw material A” or “raw material B” is stored in the “raw material identification information” item. The information such as the “raw material A” or “raw material B” is not particularly limited as long as it can identify the raw materials used to form a film on the workpiece W. As an example, the information may be the name of a compound of the raw materials used to form a film. For example, when the “film F” is polyurea, the “raw material A” and the “raw material B” may be 1,3-bis (isocyanatomethyl) cyclohexane and 1,3-bis (aminomethyl) cyclohexane, respectively. The information such as the “raw material A” or “raw material B” may be a symbol or a number indicating raw materials determined by a user.

The “first vapor pressure curve data” and the “second vapor pressure curve data” are data for specifying the saturation vapor pressure curves for the raw materials used to form a film on the workpiece W. For example, in a case where the saturation vapor pressure curve is approximated by a straight line indicated by the logarithm of the saturation vapor pressure of the raw material and the reciprocal of the absolute temperature of the workpiece W, the slope of the straight line and the intercept of the straight line are stored in the “first vapor pressure curve data” and the “second vapor pressure curve data” items, respectively.

In the example illustrated in FIG. 4, for example, in the case where the “raw material identification information” is the “raw material A”, the “S(A)” and “I(A)” are respectively stored in the “first vapor pressure curve data” item and the “second vapor pressure curve data” item. For example, in the case where the “raw material identification information” is the “raw material B”, the “S(B)” and “I(B)” are respectively stored in the “first vapor pressure curve data” item and the “second vapor pressure curve data” item. Each of the “S(A)”, “I(A)”. “S(B)”, and “I(B)” is a numerical value. Each of the “S(A)”, “I(A)”, “S(B)”, and “I(B)” may be one that is determined in advance by experiment.

In the example illustrated in FIG. 4, the saturation vapor pressure curve data 111 stores the data “S(A)”, “I(A)”, “S(B)”, and “I(B)” of the saturation vapor pressure curves for the “raw material A” and the “raw material B” used to form the “film F”. The saturation vapor pressure curve data 111 stores, for example, data of saturation vapor pressure curves for two types of raw materials (“raw material C” and “raw material D”), which are different from the “raw material A” and the “raw material B” used to form the “film F”. The saturation vapor pressure curve data 111 stores, for example, data of saturation vapor pressure curves for three or more types of raw materials (“raw material X”, “raw material Y”, and “raw material Z”) used to form the “film F”.

The saturation vapor pressure set value 112 includes at least the predetermined saturation vapor pressure value set for the workpiece W. The saturation vapor pressure set value 112 may include a saturation vapor pressure value set for at least one of the chamber 10 and the exhaust pipe 15. The saturation vapor pressure set value 112 may include a saturation vapor pressure value set for the collection device 16.

An example of the saturation vapor pressure set value 112 included in the control device 100 according to an embodiment of the present disclosure will be described here with reference to FIG. 5. FIG. 5 is a diagram illustrating the example of the saturation vapor pressure set value 112 included in the control device 100 according to an embodiment of the present disclosure. In the example illustrated in FIG. 5, the saturation vapor pressure set value 112 includes items such as a “temperature control target” and a “saturation vapor pressure set value”. In the saturation vapor pressure set value 112, information stored in the “temperature control target” item and the “saturation vapor pressure set value” item are associated with each other.

The “temperature control target” is an identification information for identifying a target whose temperature is controlled by the control device 100. The target whose temperature is controlled by the control device 100 may be a target used in the film forming apparatus 1 or a member constituting the film forming apparatus 1. In the example illustrated in FIG. 5, for example, the information such as the “workpiece”, “chamber”, “exhaust pipe”, or “collection device” is stored in the “temperature control target” item.

The “saturation vapor pressure set value” is a preset target saturation vapor pressure value of a vacuum atmosphere around the target whose temperature is controlled by the control device 100. In the example illustrated in FIG. 5, for example, information such as “P₁”, “P₂”, or “P₃” is stored in the “saturation vapor pressure set value” item. Each of “P₁”, “P₂”, and “P₃” is a numerical value.

In the example illustrated in FIG. 5, the saturation vapor pressure set value 112 stores “P₁” as a first saturation vapor pressure value set for the “workpiece”. Also, the saturation vapor pressure set value 112 stores “P₂” as second saturation vapor pressure values set for both the “chamber” and the “exhaust pipe”, and “P₃” as a third saturation vapor pressure value set for the “collection device”. The second saturation vapor pressure value “P₂” may be set for one of the “chamber” and the “exhaust pipe”.

The second saturation vapor pressure value “P₂” is higher than the first saturation vapor pressure value “P₁”. The third saturation vapor pressure value “P₃” is lower than the first saturation vapor pressure value “P1”. The first saturation vapor pressure value “P₁” may be higher than 10 mTorr (1.3332 Pa) and less than 1 Torr (133.32 Pa). For example, the first saturation vapor pressure value “P₁” may be 0.1 Torr (13.332 Pa). The second saturation vapor pressure value “P₂” may be 1 Torr (133.32 Pa) or more. For example, the second saturation vapor pressure value “P₂” may be 1 Torn (133.32 Pa). The third saturation vapor pressure value “P₃” may be 10 mTorr (1.3332 Pa) or less. For example, the third saturation vapor pressure value “P₃” may be 10 mTorr (1.3332 Pa).

As illustrated in FIG. 3, the control part 120 includes a reception part 121, an acquisition part 122, a selection part 123, a calculation part 124, and a controller 125. An internal configuration of the control part 120 is not limited to the configuration illustrated in FIG. 3, but may be another configuration as long as it performs a process to be described later. The connection relationship between processing parts included in the control part 120 is not limited to that illustrated in FIG. 3, but may be another connection relationship.

The reception part 121 receives, from the user, the identification information for identifying the raw material A and the raw material B used to form a film on the workpiece W. The reception part 121 outputs the identification information received from the user to the acquisition part 122.

The acquisition part 122 acquires the data of the saturation vapor pressure curves for the raw material A and the raw material B from the information stored in the saturation vapor pressure curve data 111. Specifically, the acquisition part 122 acquires the information of “S(A)” and “I(A)” stored in the “first vapor pressure curve data” item and the “second vapor pressure curve data” item in relation to the information of the “raw material A” stored in the “raw material identification information” item. The acquisition part 122 acquires the information of “S(B)” and “I(B)“stored in the” first vapor pressure curve data” and the “second vapor pressure curve data” in relation to the information of the “raw material B” stored in the “raw material identification information” item.

The acquisition part 122 outputs the information of the data “S(A)” and “I(A)” of the saturation vapor pressure curve for the raw material A, and the information of the data “S(B)” and “I(B)” of the saturation vapor pressure curve for the raw material B to the selection part 123 and the calculation part 124.

The acquisition part 122 acquires, from the information stored in the saturation vapor pressure set value 112, the first saturation vapor pressure value set for the workpiece W. Specifically, the acquisition part 122 acquires the information of “P₁” stored in the “saturation vapor pressure set value” item in relation to the information of the “workpiece” stored in the “temperature control target” item.

Furthermore, the acquisition part 122 acquires the second saturation vapor pressure value set for both the chamber 10 and the exhaust pipe 15. Specifically, the acquisition part 122 acquires the information of “P₂” stored in the “saturation vapor pressure set value” item in relation to the information of the “chamber” and the “exhaust pipe” stored in the “temperature control target” item.

In addition, the acquisition part 122 acquires the third saturation vapor pressure value set for the collection device 16. Specifically, the acquisition part 122 acquires the information of “P₃” stored in the “saturation vapor pressure set value” item in relation to the information of the “collection device” stored in the “temperature control target” item.

The acquisition part 122 outputs the information on the first saturation vapor pressure value P₁, the second saturation vapor pressure value P₂, and the third saturation vapor pressure value P₃ to the calculation part 124.

The selection part 123 selects the raw material A which is a raw material having a relatively low saturation vapor pressure at a certain temperature, among the raw material A and the raw material B, based on the data of the saturation vapor pressure curves of the raw material A and the raw material B.

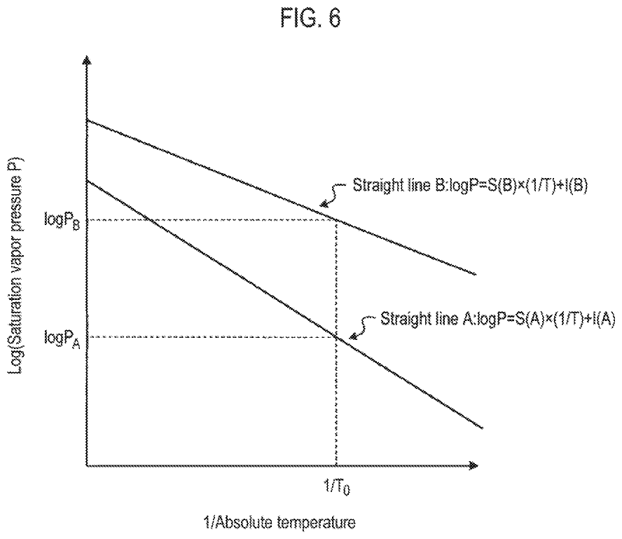

An example of an operation of the selection part 123 included in the control device 100 according to an embodiment of the present disclosure will be described with reference to FIG. 6. FIG. 6 is a diagram illustrating the example of the operation of the selection part 123 included in the control device 10) according to an embodiment of the present disclosure.

The selection part 123 calculates a logarithm log P_{A} of a saturation vapor pressure P_{A} of the raw material A at a certain temperature T₀ based on the data S(A) and I(A) of the saturation vapor pressure curve of the raw material A and an equation of a straight line A indicated by log P=S(A)×(1/T)+I(A). That is to say, the selection part 123 calculates log P_{A}=S(A)×(1/T₀)+I(A) based on the S(A) and I(A) and the equation of log P=S(A)×(1/T)+I(A). The selection part 123 calculates the saturation vapor pressure P_{A} of the raw material A at the certain temperature T₀.

The selection part 123 calculates a logarithm log P_{B} of a saturation vapor pressure of the raw material B at the certain temperature T₀ based on the data S(B) and I(B) and an equation of a straight line B indicated by log P=S(B)×(1/T)+I(B) of the saturation vapor pressure curve of the raw material B. That is to say, the selection part 123 calculates log P_{B}=S(B)×(1/T₀)+I(B) based on the S(B) and I(B) and the equation of log P=S(B)×(1/T)+I(B). The selection part 123 calculates the saturation vapor pressure P_{B} of the raw material B at the certain temperature T₀.

Here, the temperature T₀ is not particularly limited, but may be a temperature ranging from 50 degrees C. (323 K) to 150 degrees C. (432 K). The selection part 123 compares the saturation vapor pressure P_{A} of the raw material A at the certain temperature T₀ and the saturation vapor pressure P_{B} of the raw material B at the certain temperature T₀. As illustrated in FIG. 6, the selection part 123 determines that the saturation vapor pressure P_{A} of the raw material A at the certain temperature T₀ is lower than the saturation vapor pressure P_{B} of the raw material B at the certain temperature T₀. As a result, the selection part 123 selects the raw material A which is a raw material having a relatively low saturation vapor pressure P_{A} at the certain temperature T₀, among the raw material A and the raw material B.

The selection part 123 outputs the selection result of the raw material A, which is a raw material having a relatively low saturation vapor pressure P_{A} at the certain temperature T₀, to the calculation part 124.

The calculation part 124 calculates a first temperature T₁ corresponding to the first saturation vapor pressure value P₁ for the selected raw material A based on the data of the saturation vapor pressure curve for the selected raw material A.

Furthermore, the calculation part 124 calculates a second temperature T₂ corresponding to the second saturation vapor pressure value P₂ for the selected raw material A based on the data of the saturation vapor pressure curve for the selected raw material A.

In addition, the calculation part 124 calculates a third temperature T₃ corresponding to the third saturation vapor pressure value P₃ for the selected raw material A based on the data of the saturation vapor pressure curve for the selected raw material A.

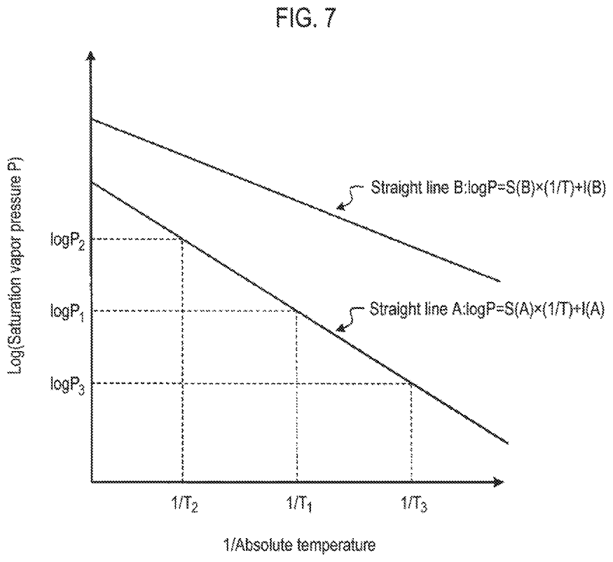

An example of an operation of the calculation part 124 included in the control device 100 according to an embodiment of the present disclosure will be described with reference to FIG. 7. FIG. 7 is a diagram illustrating the example of the operation of the calculation part 124 included in the control device 100 according to an embodiment of the present disclosure.

The calculation part 124 calculates the first temperature T₁ corresponding to the first saturation vapor pressure value P₁ for the selected raw material A based on the data S(A) and I(A) of the saturation vapor pressure curve, the first saturation vapor pressure value P₁, and the equation of the straight line A for the selected raw material A. That is to say, the calculation part 124 calculates T₁=S(A)/(log P₁−I(A)) based on the S(A) and I(A), P₁, and the equation of log P=S(A)×(1/T)+I(A).

Furthermore, the calculation part 124 calculates the second temperature T₂ corresponding to the second saturation vapor pressure value P₂ for the selected raw material A based on the data S(A) and I(A) of the saturation vapor pressure curve, the second saturation vapor pressure value P₂, and the equation of the straight line A for the selected raw material A. That is to say, the calculation part 124 calculates T₂=S(A)(log P₂−I(A)) based on the S(A) and I(A), P₂, and the equation of log P=S(A)×(1/T)+I(A).

In addition, the calculation part 124 calculates the third temperature T₃ corresponding to the third saturation vapor pressure value P₃ for the selected raw material A based on the data S(A) and I (A) of the saturation vapor pressure curve, the third saturation vapor pressure value P₃, and the equation of the straight line A for the selected raw material A. That is to say, the calculation part 124 calculates T₃=S(A)/(log P₃−I(A)) based on the S(A) and I(A), P₃, and the equation of log P=S(A)×(1/T)+I(A).

As illustrated in FIG. 7, since the second saturation vapor pressure value P₂ is higher than the first saturation vapor pressure value P₁, the second temperature T₂ is higher than the first temperature T₁. Since the third saturation vapor pressure value P₃ is lower than the first saturation vapor pressure value P₁, the third temperature T₃ is lower than the first temperature T₁.

The controller 125 controls the temperature of the workpiece W to the first temperature T₁. The controller 125 controls the temperatures of both the chamber 10 and the exhaust pipe 15 to the second temperature T₂. The controller 125 controls the temperature of the collection device 16 to the third temperature T₃. The controller 125 also may control the temperature of one of the chamber 10 and the exhaust pipe 15 to the second temperature T₂.

As described above, the control device 100 according to an embodiment of the present disclosure includes the acquisition part 122, the selection part 123, the calculation part 124, and the controller 125. The acquisition part 122 acquires the data of the saturation vapor pressure curves of the raw material A and the raw material B used to form a film on the workpiece W and the predetermined saturation vapor pressure value P₁ set for the workpiece W. The selection part 123 selects the raw material A having a relatively low saturation vapor pressure at the certain temperature T₀, among the raw material A and the raw material B, based on the data of the saturation vapor pressure curves. The calculation part 124 calculates the temperature T₁ corresponding to the predetermined saturation vapor pressure value P₁ for the selected raw material A based on the data of the saturation vapor pressure curve for the selected raw material A. The controller 125 controls the temperature of the workpiece W to the calculated temperature T₁.

In the control device 100, the temperature of the workpiece W is controlled to the temperature T₁ corresponding to the predetermined saturation vapor pressure value P₁ for the selected raw material A so that a film can be formed on the workpiece W at a predetermined range of film-forming rate. Thus, in the control device 100, the flow rate of the raw material A is controlled so that the vapor pressure (partial pressure) of the raw material A is equal to the predetermined saturation vapor pressure P₁, but the tolerance of the flow rate of the raw material B having a relatively high saturation vapor pressure at the certain temperature T₀ can be increased. Accordingly, it is possible to provide the control device 100 capable of easily controlling the formation of a film from the raw material A and the raw material B.

The film forming apparatus 1 according to an embodiment of the present disclosure includes the chamber 10, the first raw material source 11a and the second raw material source 11b, the first supply pipe 13a and the second supply pipe 13b, and the exhaust pipe 15, and the control device 100. The workpiece W is carried into the chamber 10. The first raw material source 11a and the second raw material source 11b respectively store the raw material A and the raw material B used to form a film on the workpiece W. The first supply pipe 13a and the second supply pipe 13b respectively supply the material A and the material B into the chamber 10. The exhaust pipe 15 is connected to the chamber 10. Thus, it is possible to provide the film forming apparatus 1 that is capable of easily controlling the formation of a film from the raw material A and the raw material B.

In the control device 100) according to an embodiment of the present disclosure, the acquisition part 122 acquires the first saturation vapor pressure value P₁ and the second saturation vapor pressure value P₂ higher than the first saturation vapor pressure value P₁. The first saturation vapor pressure value P₁1 is a value set for the workpiece W. The second saturation vapor pressure value P₂ is a value set for at least one of the chamber 10 into which the workpiece W is carried and the exhaust pipe 15 connected to the chamber 10. The calculation part 124 calculates the first temperature T₁ corresponding to the first saturation vapor pressure value P₁ and the second temperature T₂ corresponding to the second saturation vapor pressure value P₂ for the selected raw material A. The controller 125 controls the temperature of the workpiece W to the first temperature T₁, and controls the temperature of at least one of the chamber 10 and the exhaust pipe 15 to the second temperature T₂.

Thus, it is possible to allow a film-forming rate at which a film is formed on the workpiece W to fall within a certain range and to reduce a film-forming rate of a film in at least one of the chamber 10 and the exhaust pipe 15. This makes it possible to form a film on the workpiece W at a film-forming rate falling within a certain range and to suppress the formation of a film in at least one of the chamber 10 and the exhaust pipe 15.

In the control device 100 according to an embodiment of the present disclosure, the acquisition part 122 acquires the first saturation vapor pressure value P₁ and the third saturation vapor pressure value P₃ which is lower than the first saturation vapor pressure value P₁. The first saturation vapor pressure value P₁1 is a value set for the workpiece W. The third saturation vapor pressure value P₃ is a value set for the collection device 16 that collects particles generated in the chamber 10 into which the workpiece W is carried. The calculation part 124 calculates the first temperature T₁ corresponding to the first saturation vapor pressure value P₁ and the third temperature T₃ corresponding to the third saturation vapor pressure value P₃ for the selected raw material A. The controller 125 controls the temperature of the workpiece W to the first temperature T₁, and controls the temperature of the collection device 16 to the third temperature T₃.

Thus, it is possible to allow a film-forming rate of forming a film on the workpiece W to fall within a certain range and to increase a film-forming rate of a film in the collection device 16. This makes it possible to form a film on the workpiece W at the film-forming rate falling within the certain range and to promote production of products from the raw material A and the raw material B for forming the film in the collection device 16 (to facilitate collection of non-reacted raw materials A and B remaining in an unreacted state).

In the control device 100 according to an embodiment of the present disclosure, the raw material A is a raw material having a relatively low saturation vapor pressure at the certain temperature T₀, and the raw material B is a raw material having a saturation vapor pressure at least 10 times higher than that of the raw material A at the certain temperature T₀.

Thus, the flow rate of the raw material A is controlled so that the vapor pressure (partial pressure) of the raw material A is equal to a predetermined saturation vapor pressure, but the tolerance of the flow rate of the raw material B having a relatively high saturation vapor pressure at the certain temperature T₀ can be more reliably increased. Accordingly, it is possible to more easily control the formation of a film from the raw material A and the raw material B.

### <Processing Sequence of Control Method>

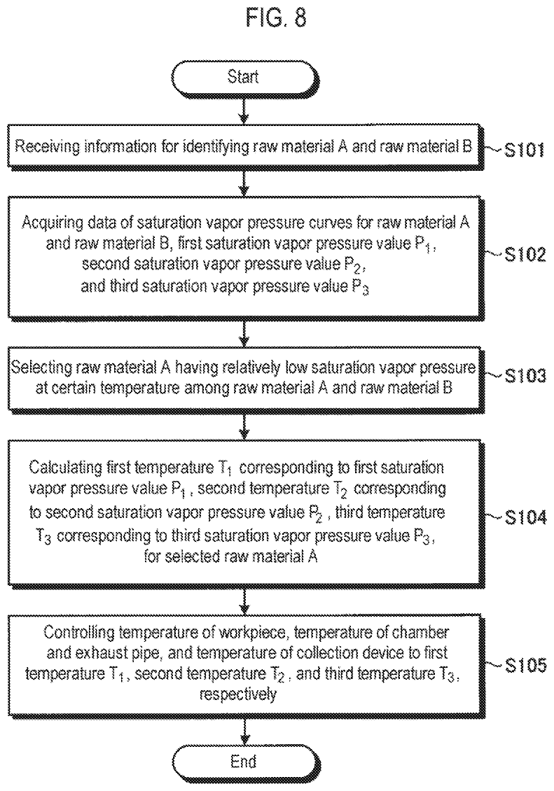

Next, an example of a processing sequence of the control method according to an embodiment of the present disclosure will be described with reference to FIG. 8. FIG. 8 is a flowchart illustrating the example of the processing sequence of the control method according to an embodiment of the present disclosure.

In step S101, the control device 100 receives, from the user, information for identifying the raw material A and the raw material B as raw materials used to form a film on the workpiece W.

In step S102, the control device 100 acquires data of the saturation vapor pressure curves for the raw material A and the raw material B from the saturation vapor pressure curve data 111 based on the information for identifying the raw material A and the raw material B. Furthermore, in step S102, the control device 100 acquires the first saturation vapor pressure value P₁, the second saturation vapor pressure value P₂, and the third saturation vapor pressure value P₃ from the saturation vapor pressure set value 112. The first saturation vapor pressure value P₁, the second saturation vapor pressure value P₂, and the third saturation vapor pressure value P₃ are respectively values set for the workpiece W, the chamber 10 and the exhaust pipe 15, and the collection device 16. The first saturation vapor pressure value P₁, the second saturation vapor pressure value P₂, and the third saturation vapor pressure value P₃ have a relationship of P₂>P₁>P₃.

In step S103, the control device 100 selects the raw material A which is a raw material having a relatively low saturation vapor pressure at a certain temperature, among the raw material A and the raw material B, based on the data of the saturation vapor pressure curves of the raw material A and the raw material B.

In step S104, the control device 100 calculates the first temperature T₁, the second temperature T₂, and the third temperature T₃ based on the data of the saturation vapor pressure curve for the selected raw material A. The first temperature T₁ is a temperature corresponding to the first saturation vapor pressure value P₁ for the selected raw material A. The second temperature T₂ is a temperature corresponding to the second saturation vapor pressure value P₂ for the selected raw material A. The third temperature T₃ is a temperature corresponding to the third saturation vapor pressure value P₃ for the selected raw material A. The first temperature T₁, the second temperature T₂, and the third temperature T₃ have a relationship of T₂>T₁>T₃.

In step S105, the control device 100 controls the temperature of the workpiece W, the temperature of the chamber 10 and the exhaust pipe 15, and the temperature of the collection device 16 to the first temperature T₁, the second temperature T₂, and the third temperature T₃, respectively.

### <Processing Sequence of Film Forming Method>

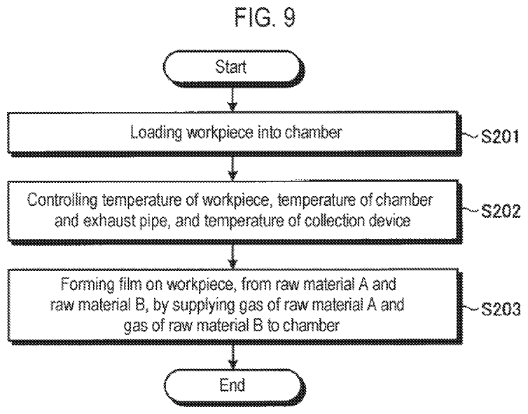

Next, an example of a processing sequence of a film forming method according to an embodiment of the present disclosure will be described with reference to FIG. 9. FIG. 9 is a flowchart illustrating the example of the processing sequence of the film forming method according to an embodiment of the present disclosure.

In step S201, the film forming apparatus 1 loads the workpiece W into the chamber 10.

In step S202, the film forming apparatus 1 controls the temperature of the workpiece W, the temperature of the chamber 10 and the exhaust pipe 15, and the temperature of the collection device 16 using the control device 100. The processing in step S202 is similar to the processing in steps S101 to S105 illustrated in FIG. 8.

In step S203, the film forming apparatus 1 forms a film on the workpiece W from the raw material A and the raw material B by supplying a gas of the raw material A and a gas of the raw material B into the chamber 10.

### <Raw Material A and Raw Material B>

The raw material A and the raw material B are selected depending on a film to be formed on the workpiece W. For example, the raw material A and the raw material B may be an aliphatic compound, an alicyclic compound, an aromatic alkyl compound, or an aromatic compound, independently of one another.

The film formed on the workpiece may be a polymer or a non-polymer produced from the raw material A and the raw material B. The polymer is a compound having a molecular weight of 10,000 or more, which is obtained by polymerizing the raw material A and the raw material B. The non-polymer is a compound produced from the raw material A and the raw material B other than the polymer. For example, in a case where each of the raw material A and the raw material B is a bifunctional compound, a film formed on the workpiece W is a polymer produced by a copolymerization reaction. For example, in a case where each of the raw material A and the raw material B is a mono-functional compound, a film formed on the workpiece W is a non-polymer (dimer) produced by a bimolecular reaction. For example, in a case where one of the raw material A and the raw material B is a bifunctional compound and the other is a mono-functional compound, a film formed on the workpiece W is a non-polymer (trimmer) produced by a trimolecular reaction.

For example, the raw material A having a relatively low saturation vapor pressure at the certain temperature T₀ and the raw material B having a relatively high saturation vapor pressure at the certain temperature T₀ may be a bifunctional compound and a mono-functional compound, respectively. In this case, the raw material B is supplied into the chamber 10 at a more sufficient flow rate than the flow rate of the raw material A supplied into the chamber 10. In this case, an end-free non-polymer (trimer) of the bifunctional compound can be obtained. Thus, it is possible to obtain a non-polymer (trimer) film having uniform film properties.

In a case where a film formed on the workpiece W is a polymer or a non-polymer having a 2-aminoethanol bond (—NH—CH₂—CH(OH)—), the raw material A and the raw material B may be epoxide and amine, respectively. In a case where a film formed on the workpiece W is a polymer (polyurethane) or a non-polymer having a urethane bond (—NH—CO—O—), the raw material A and the raw material B may be isocyanate and alcohol, respectively. In a case where a film formed on the workpiece W is a polymer (polyurea) or a non-polymer having a urea bond (—NH—CO—NH—), the raw material A and the raw material B may be isocyanate and amine, respectively. In a case where a film formed on the workpiece W is a polymer (polyamide) or a non-polymer having an amide bond (—NH—CO—), the raw material A and the raw material B may be acyl halide and amine, respectively. In a case where a film formed on the workpiece W is a polymer (polyimide) or a non-polymer having an imide bond (—CO—N(-)—CO—), the raw material A and the raw material B may be carboxylic acid anhydride and amine, respectively.

In a case where a film formed on the workpiece W is polyurethane, the polyurethane may be depolymerized into isocyanate and alcohol by heating it to a predetermined temperature or higher. In a case where a film formed on the workpiece W is polyurea, the polyurea may be depolymerized into isocyanate and amine by heating it to a predetermined temperature or higher.

An example in which a film formed on the workpiece W is a polymer (polyurea) or a non-polymer having a urea bond will be described. By selecting isocyanate as the raw material A and diamine as the raw material B, various films that are polymers (poly urea) or non-polymers having a urea bond may be formed.

For example, a linear polyurea may be produced by using diisocyanate as the raw material A and diamine (e.g., primary amine) as the raw material B. A combination of diisocyanate and diamine may be a combination of 4,4′-diphenylmethane diisocyanate (MDI) and 1,12-diaminododecane (DAD). A combination of diisocyanate and diamine may be a combination of 1,3-bis (isocyanatomethyl) cyclohexane (H6XDI) and 1,12-diaminododecane (DAD). A combination of diisocyanate and diamine may be a combination of 1,3-bis (isocyanatomethyl) cyclohexane (H6XDI) and 1,3-bis (aminomethyl) cyclohexane (H6XDA). A combination of diisocyanate and diamine may be a combination of 1,3-bis (isocyanatomethyl) cyclohexane (H6XDI) and hexamethylene diamine (HMDA). A combination of diisocyanate and diamine may be a combination of m-xylylene diisocyanate (XDI) and m-xylylene diamine (XDA). A combination of diisocyanate and diamine may be a combination of m-xylylene diisocyanate (XDI) and benzylamine (BA).

For example, a cross-linkable polyurea may be produced by using diisocyanate as the raw material A and triamine (e.g., primary amine) or tetraamine (e.g., secondary amine) as the raw material B. A trimer having a urea bond may be produced by using monoisocyanate as the raw material A and diamine (e.g., primary amine) as the raw material B. A dimer having a urea bond may be produced by using monoisocyanate as the raw material A and monoamine (e.g., primary amine) as the raw material B.

An example in which a film formed on the workpiece W is a polymer (polyimide) having an imide bond will be described. For example, a combination of the raw material A and the raw material B which enables to produce polyimide may be a combination of pyromellitic dianhydride (PMDA) and 4,4′-oxydianiline (44ODA). A combination of the raw material A and the raw material B which enables to produce polyimide may be a combination of pyromellitic dianhydride (PMDA) and hexamethylene diamine (HMDA).

The raw material A is a raw material having a relatively low saturation vapor pressure at a certain temperature, and the raw material B is a raw material having a saturation vapor pressure at least 10 times higher than that of the raw material A at the certain temperature. For example, the raw material A and the raw material B are 1,3-bis (isocyanatomethyl) cyclohexane (H6XDI) and 1,3-bis (aminomethyl) cyclohexane (H6XDA), respectively. For example, the raw material A and the raw material B may be m-xylylene diisocyanate (XDI) and benzylamine (BA), respectively.

In the aforementioned embodiments, there has been described the case where plural types of raw materials used to form a film on the workpiece W are two types of raw materials (the raw material A and the raw material B), but the plural types of raw materials used to form a film on the workpiece W may be three or more types of raw materials. For example, in a case where plural types of raw materials are three types of raw materials having two types of bifunctional compounds and one kind of monofunctional compound, the film formed on the workpiece W may be a polymer produced by a copolymerization reaction.

In the case where the plural types of raw materials are three or more types of raw materials, the film forming apparatus 1 may include a plurality of raw material sources, a plurality of vaporizers, and a plurality of supply pipes according to the number of types of raw materials. The reception part 121 receives, from the user, identification information for identifying the plural types of raw materials used to form a film on the workpiece W. The acquisition part 122 acquires data of the saturation vapor pressure curves for the plural types of raw materials used to form a film on the workpiece W. The selection part 123 selects a raw material having the lowest saturation vapor pressure at a certain temperature, among the plural types of raw materials, based on the data of the saturation vapor pressure curves. The plural types of raw materials may include a raw material having the lowest saturation vapor pressure at a certain temperature T₀ and at least one raw material having a saturation vapor pressure at least 10 times higher than the lowest saturation vapor pressure at the certain temperature T₀.

### MODIFICATIONS

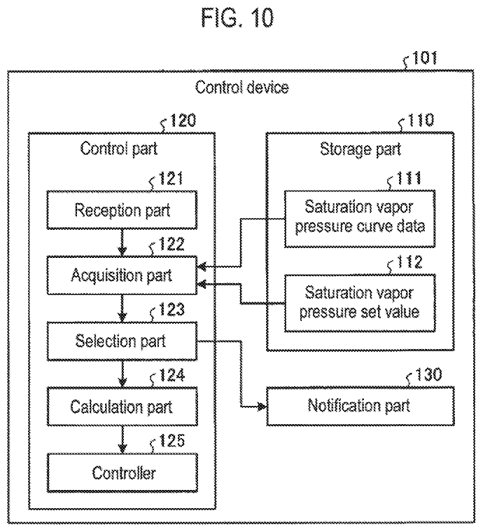

Next, an example of a configuration of a control device 101 according to a modification of the embodiment of the present disclosure will be described with reference to FIG. 10. FIG. 10 is a block diagram illustrating the example of the configuration of the control device 101 according to the modification of the embodiment of the present disclosure. The control device 101 illustrated in FIG. 10 further includes a notification part 130, in addition to the storage part 110 and the control part 120 included in the control device 100 illustrated in FIG. 3. Among the functions of the processing parts included in the control device 101 illustrated in FIG. 10, descriptions of the same functions as the functions of the respective processing parts included in the control device 100 illustrated in FIG. 3 will be omitted.

As described above, the reception part 121 of the control device 100 receives, from the user, the identification information for identifying the raw material A and the raw material B used to form a film on the workpiece W. On the other hand, the reception part 121 of the control device 101 receives, from the user, an identification information for identifying a film formed on the workpiece W. For example, the reception part 121 receives an identification information for identifying the “film F”.

As described above, the acquisition part 122 of the control device 100 acquires the data of the saturation vapor pressure curves for the raw material A and the raw material B. On the other hand, the acquisition part 122 of the control device 101 acquires identification information for identifying the plural types of raw materials used to form a film on the workpiece W and the data of the saturation vapor pressure curves for the plural types of raw materials, among the information stored in the saturation vapor pressure curve data 111. For example, the acquisition part 122 acquires all of the information stored in the “raw material identification information” item, the “first vapor pressure curve data” item, and the “second vapor pressure curve data” item in relation to the information of the “film F” stored in the “film identification information” item. In the example illustrated in FIG. 4, the acquisition part 122 acquires “S(A)” and “I(A)” for the “raw material A”, . . . , “S(Z)” and “I(Z)” for the “raw material Z”. The acquisition part 122 of the control device 101 outputs the identification information for identifying the plural types of raw materials used to form a film on the workpiece W and the data of the saturation vapor pressure curves for the plural types of raw materials, to the selection part 123 and the calculation part 124.

As described above, the selection part 123 of the control device 100 selects the raw material A, which is a raw material having a relatively low saturation vapor pressure at the certain temperature T₀, among the raw material A and the raw material B, based on the data of the saturation vapor pressure curves of the raw material A and the raw material B. On the other hand, the selection part 123 of the control device 101 selects a raw material having the lowest saturation vapor pressure at the certain temperature T₀, among the plural types of raw materials, based on the data of the saturation vapor pressure curves of the plural types of raw materials. In the example illustrated in FIG. 4, for example, the selection part 123 of the control device 101 selects the “raw material A” which is a raw material having the lowest saturation vapor pressure at the certain temperature T₀, among the “raw material A”, . . . , the “raw material Z” that are the plural types of raw materials for forming the “film F”. Hereinafter, the raw material having the lowest saturation vapor pressure at the certain temperature T₀ will be referred to as a “lowest saturation vapor pressure raw material”.

In addition, the selection part 123 of the control device 101 selects a raw material having a saturation vapor pressure at least 10 times higher than that of the lowest saturation vapor pressure raw material at the certain temperature T₀, among the plural types of raw materials, based on the data of the saturation vapor pressure curves of the plural types of raw materials. Hereinafter, the raw material having a saturation vapor pressure at least 10 times higher than that of the lowest saturation vapor pressure raw material at the certain temperature T₀ is sometimes referred to as a “relatively high saturation vapor pressure raw material”. The relatively high saturation vapor pressure raw material reacts with the lowest saturation vapor pressure raw material. In the example illustrated in FIG. 4, among the plural types of raw materials “raw material A”, . . . , the “raw material Z” for forming the “film F”, for example, the “raw material B”, which reacts with the “raw material A” and has a saturation vapor pressure at least 10 times higher than that of the “raw material A” at the certain temperature T₀, is selected.

The selection part 123 of the control device 101 outputs, to the notification part 130, the identification information for identifying the lowest saturation vapor pressure raw material and the identification information for identifying the relatively high saturation vapor pressure raw material.

The calculation part 124 of the control device 101 has the same function as the calculation part 124 of the control device 100. The controller 125 of the control device 101 has the same function as the controller 125 of the control device 100.

When the notification part 130 included in the control device 101 receives the identification information outputted from the selection part 123 of the control device 101, the notification part 130 notifies the user of the lowest saturation vapor pressure raw material and the relatively high saturation vapor pressure raw material as the plural types of raw materials for forming a film. The notification part 130 is realized by, for example, a display device such as a liquid crystal display, which displays the lowest saturation vapor pressure raw material and the relatively high saturation vapor pressure raw material. In the example illustrated in FIG. 4, for example, the notification part 130 notifies the user of the “raw material A” as the lowest saturation vapor pressure raw material and the “raw material B” as the relatively high saturation vapor pressure raw material as the plural types of raw materials for forming the “film F”.

As described above, in the control device 101 according to the modification of the embodiment of the present disclosure, the acquisition part 122 acquires the identification information for identifying the plural types of raw materials used to form a film on the workpiece W and the data of the saturation vapor pressure curves for the plural types of raw materials. The selection part 123 selects a raw material having the lowest saturation vapor pressure at the certain temperature T₀, and at least one raw material which reacts with the respective raw material and has a saturation vapor pressure at least 10 times higher than the lowest saturation vapor pressure at the certain temperature T₀, among the plural types of raw materials of a film, based on the data of the saturation vapor pressure curves. The notification part 130 notifies the user of the information on the raw material having the lowest saturation vapor pressure at the certain temperature T₀ and the at least one raw material which reacts with the respective raw material and has a saturation vapor pressure at least 10 times higher than the lowest saturation vapor pressure at the certain temperature T₀.

This make it possible to control the flow rate of the raw material having the lowest saturation vapor pressure at the temperature T₀, and to more reliably increase the tolerance of the flow rate of the at least one raw material having a saturation vapor pressure at least 10 times higher than the lowest saturation vapor pressure at the certain temperature T₀. Thus, it is possible to notify the user of information on the plural types of raw materials, and thus enabling the user to more easily control the formation of a film.

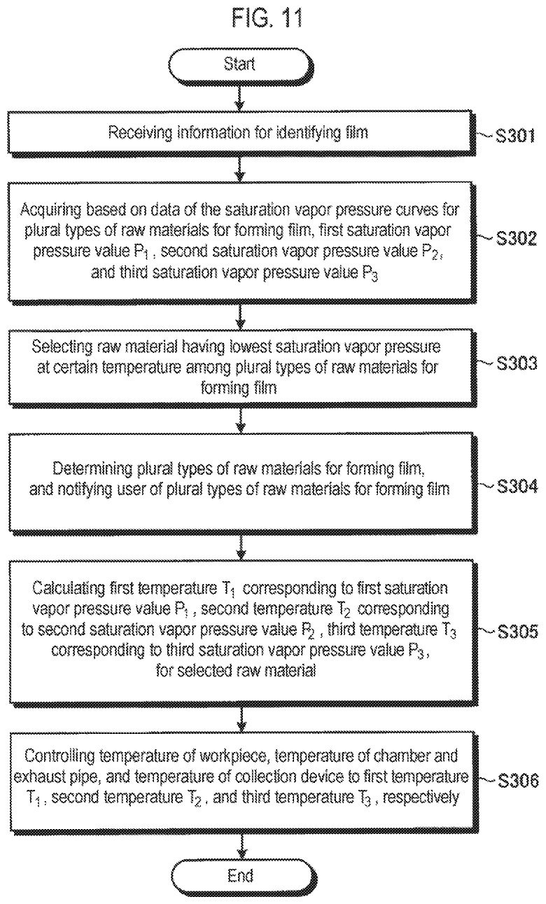

Next, an example of a processing sequence of a control method according to the modification of the embodiment of the present disclosure will be described with reference to FIG. 11. FIG. 11 is a flowchart illustrating the example of the processing sequence of the control method according to the modification of the embodiment of the present disclosure.

In step S301, the control device 101 receives, from the user, information for identifying a film to be formed on the workpiece W.

In step S302, the control device 101 acquires, from the saturation vapor pressure curve data 111, data of the saturation vapor pressure curves for plural types of raw materials for forming a film, based on the information for identifying the film. Furthermore, in step S302, the control device 101 obtains a first saturation vapor pressure value P₁, a second saturation vapor pressure value P₂, and a third saturation vapor pressure value P₃ from the saturation vapor pressure set value 112.

In step S303, the control device 101 selects a raw material having the lowest saturation vapor pressure at a certain temperature, among the plural types of raw materials for forming a film, based on the data of the saturation vapor pressure curves for the plural types of raw materials for forming a film.

In step S304, the control device 101 determines plural types of raw materials for forming a film based on the data of the saturation vapor pressure curves for the plural types of raw materials for forming a film, and notifies the user of the plural types of raw materials for forming a film. The control device 101 selects a raw material having the lowest saturation vapor pressure at a certain temperature T₀ and a raw material having a saturation vapor pressure at least 10 times higher than that of the respective raw material having the lowest saturation vapor pressure at the certain temperature T₀, and notifies the user of the same.

In step S305, the control device 101 calculates a first temperature T₁, a second temperature T₂, and a third temperature T₃ based on the data of the saturation vapor pressure curve for the selected raw material. The first temperature T₁ is a temperature corresponding to the first saturation vapor pressure value P₁ for the selected raw material. The second temperature T₂ is a temperature corresponding to the second saturation vapor pressure value P₂ for the selected raw material. The third temperature T₃ is a temperature corresponding to the third saturation vapor pressure value P₃ for the selected raw material. The first temperature T₁, the second temperature T₂, and the third temperature T₃ have a relationship of T₂>T₁>T₃.

In step S306, the control device 101 controls the temperature of the workpiece W, the temperature of the chamber 10 and the exhaust pipe 15, and the temperature of the collection device 16 to the first temperature T₁, the second temperature T₂, and the third temperature T₃, respectively.

### First Example

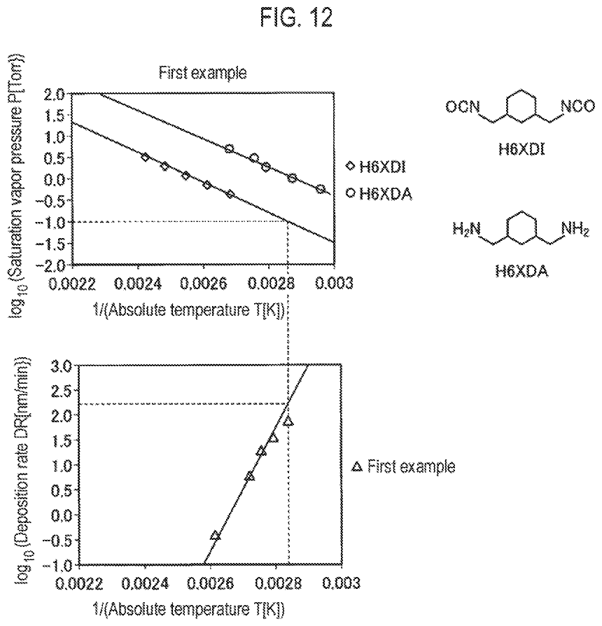

Next, a first example of the control method according to an embodiment of the present disclosure will be described with reference to FIG. 12. FIG. 12 is a diagram illustrating the first example of the control method according to an embodiment of the present disclosure.

In the first example, a polyurea film was formed on a wafer as the workpiece W using the film forming apparatus 1 as illustrated in FIG. 1. As illustrated in FIG. 12, 1,3-bis (isocyanatomethyl) cyclohexane (H6XDI) and 1,3-bis (aminomethyl) cyclohexane (H6XDA) were used as the raw materials for producing polyurea.

The control device 100 acquired a slope of −3,459.7 and an intercept of 8.888 for a straight line of log 10 (saturation vapor pressure [Torr])=−3,459.7×(1/(absolute temperature [K]))+8.888 as the data of the saturation vapor pressure curve for the raw material H6XDI. Similarly, the control device 100 acquired a slope of −3,534.2 and an intercept of 10.171 for a straight line of log 10 (saturation vapor pressure [Torr])=−3,534.2×(1/(absolute temperature [K]))+10.171 as the data of the saturation vapor pressure curve for the raw material H6XDA. In addition, the control device 100 acquired a predetermined saturation vapor pressure value of 0.1 Torr set for the wafer.

Subsequently, the control device 100 selected the raw material H6XDI which is a raw material having a relatively low saturation vapor pressure at a certain temperature, among the raw material H6XDI and the raw material H6XDA, based on the data of the saturation vapor pressure curves for the raw material H6XDI and the raw material H6XDA. The raw material H6XDA has a saturation vapor pressure of about 10 times higher than that of the raw material H6XDI at the certain temperature.

Subsequently, the control device 100 calculated a temperature of 350 K (77 degrees C.) corresponding to the predetermined saturation vapor pressure value of 0.1 Torr for the selected raw material H6XDI based on the data of the saturation vapor pressure curve for the selected raw material H6XDI. Subsequently, the control device 100 controlled the temperature of the wafer to the calculated temperature of 77 degrees C. A film-forming rate at which polyurea is formed on the wafer was 173 nm/min at the temperature of 77 degrees C. of the wafer.

### Second Example

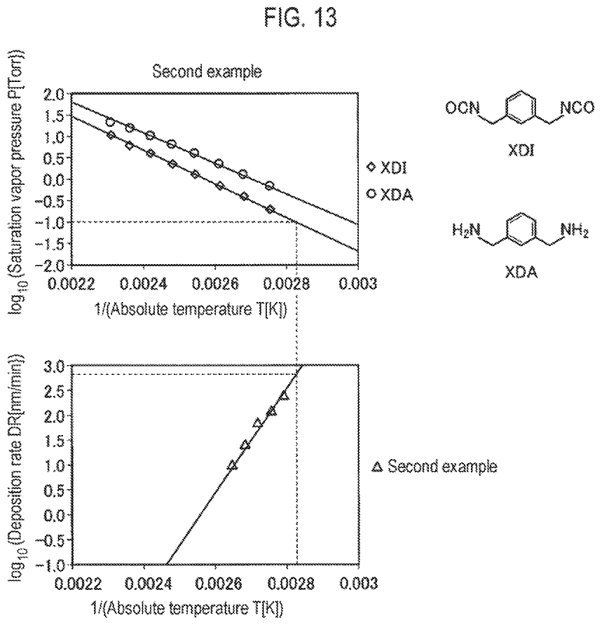

Next, a second example of the control method according to an embodiment of the present disclosure will be described with reference to FIG. 13. FIG. 13 is a diagram illustrating the second example of the control method according to an embodiment of the present disclosure.

In the second example, a polyurea film was formed on a wafer as the workpiece W using the film forming apparatus 1 as illustrated in FIG. 1. As illustrated in FIG. 13, m-xylylene diisocyanate (XDI) and m-xylylene diamine (XDA) were used as the raw materials for forming the polyurea film.

The control device 100 acquired a slope of −3.882 and a intercept of 9.9947 for a straight line of log 10 (saturation vapor pressure [Torr])=−3,882×(1/(absolute temperature [K]))+9.9947 as the data of the saturation vapor pressure curve for the raw material XDI. Similarly, the control device 100 acquired a slope of −3,376 and an intersect of 9.17 for a straight line of log 10 (saturation vapor pressure [Torr])=−3,376×(1/(absolute temperature [K]))+9.17 as the data of the saturation vapor pressure curve for the raw material XDA. In addition, the control device 100 acquired a predetermined saturation vapor pressure value of 0.1 Torr set for the wafer.

Subsequently, the control device 100 selected the raw material XDI which is a raw material having a relatively low saturation vapor pressure at a certain temperature, among the raw material XDI and the raw material XDA, based on the data of the saturation vapor pressure curves for the raw material XDI and the raw material XDA. The raw material XDA has a saturation vapor pressure of about several times higher than that of the raw material XDI at the certain temperature.

Subsequently, the control device 100 calculated a temperature of 353 K (80 degrees C.) corresponding to the predetermined saturation vapor pressure value of 0.1 Torr for the selected raw material XDI based on the data of the saturation vapor pressure curve for the selected raw material XDI. Subsequently, the control device 100 controlled the temperature of the wafer to the calculated temperature of 80 degrees C. A film-forming rate at which polyurea is formed on the wafer was 690 nm/min at the wafer temperature of 80 degrees C.

### Third Example

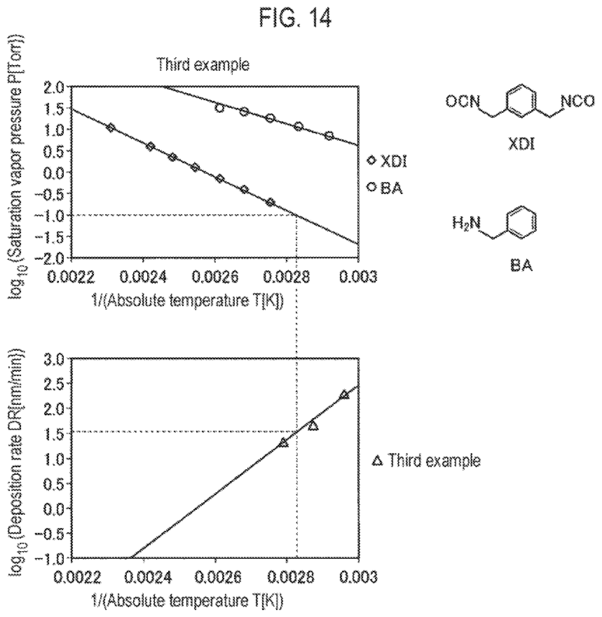

Next, a third example of the control method according to an embodiment of the present disclosure will be described with reference to FIG. 14. FIG. 14 is a diagram illustrating the third example of the control method according to an embodiment of the present disclosure.

In the third example, a polyurea film was formed on a wafer as the workpiece W using the film forming apparatus 1 as illustrated in FIG. 1. As illustrated in FIG. 14, m-xylylene diisocyanate (XDI) and benzylamine (BA) were used as the raw materials for producing poly urea.

The control device 100 acquired a slope of −3,856.8 and an intercept of 9.9288 for a straight line of log 10 (saturation vapor pressure [Torr])=−3,856.8×(1/(absolute temperature [K]))+9.9288 as the data of the saturation vapor pressure curve for the raw material XDI. Similarly, the control device 100 acquired a slope of −2,325.9 and an intercept of 7.6346 for a straight line of log 10 (saturation vapor pressure [Torr])=−2,325.9×(1/(absolute temperature [K]))+7.6346 as the data of the saturation vapor pressure curve for the raw material BA. In addition, the control device 100 acquired a predetermined saturation vapor pressure value of 0.1 Torr set for the wafer.

Subsequently, the control device 100 selected the raw material XDI which is a raw material having a relatively low saturation vapor pressure at a certain temperature, among the raw material XDI and the raw material BA, based on the data of the saturation vapor pressure curves for the raw material XDI and the raw material BA. The raw material BA has a saturation vapor pressure of about 100 times higher than that of the raw material XDI at the certain temperature.

Subsequently, the control device 100 calculated a temperature of 353 K (80 degrees C.) corresponding to the predetermined saturation vapor pressure value of 0.1 Torr for the selected raw material XDI based on the data of the saturation vapor pressure curve for the selected raw material XDI. Subsequently, the control device 100 controlled the temperature of the wafer to the calculated temperature of 80 degrees C. A film-forming rate at which polyurea is formed on the wafer was 32 nm min at the wafer temperature of 80 degrees C.

### <Hardware Configuration>

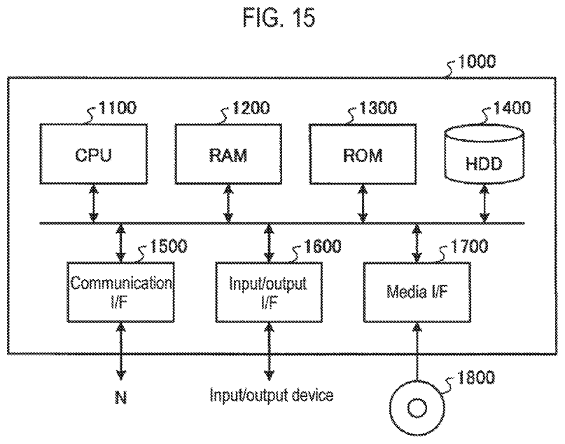

The control devices 100 and 101 described above are realized by, for example, a computer 1000 having a configuration as illustrated in FIG. 15. FIG. 15 is a hardware configuration diagram illustrating an example of a computer that realizes the functions of the control devices 100 and 101. The computer 1000 includes a central processing unit (CPU) 1100, an RAM 1200, a read only memory (ROM) 1300, and a hard disk drive (HDD) 1400. In addition, the computer 1000 includes a communication interface (I/F) 1500, an input/output interface (I/F) 1600, and a media interface (I/F) 1700.

The CPU 1100 performs the controls of the respective parts by operating based on a program stored in the ROM 1300 or the HDD 1400. The ROM 1300 stores a booting program executed by the CPU 1100 when the computer 1000 starts up, a program depending on the hardware of the computer 1000, and the like.

The HDD 1400 stores the program executed by the CPU 1100, data used by such program, and the like. The communication interface 1500 receives data from another device and transmits the data to the CPU 1100 via a network N, and transmits data generated by the CPU 1100 via the network N to another device.

The CPU 1100 controls an output device such as a display or a printer and an input device such as a keyboard or a mouse via the input/output interface 1600. The CPU 1100 acquires data from the input device via the input/output interface 1600. The CPU 1100 outputs the generated data to the output device via the input/output interface 1600.

The media interface 1700 reads a program or data stored in a recording medium 1800 and provides the same to the CPU 1100 via the RAM 1200. The CPU 1100 loads such a program from the recording medium 1800 onto the RAM 1200 via the media interface 1700 and executes the loaded program. Examples of the recording medium 1800 may include an optical recording medium such as a digital versatile disc (DVD) or a phase change rewritable disk (PD), a magneto-optical recording medium such as a magneto-optical disk (MO), a tape medium, a magnetic recording medium, or a semiconductor memory, or the like.

For example, in the case where the computer 1000 functions as the control device 100 or 101, the CPU 1100 of the computer 1000 realizes the function of the control device 100 or 101 by executing the program loaded on the RAM 1200. The CPU 1100 of the computer 1000 reads such a program from the recording medium 1800 and executes the same. Alternatively, the CPU 1100 of the computer 1000 may acquire such a program from another device via the network N.

Furthermore, among the respective processes described in the aforementioned embodiments, some or all of the processes described as being automatically performed may be manually performed. In addition, information including the processing sequences, specific names, and various data and parameters illustrated in this specification or drawings may be arbitrarily changed unless otherwise specified. For example, various information illustrated in the respective drawings are not limited to the illustrated information.

Furthermore, each component of each device as illustrated is functionally conceptual, and does not necessarily have to be physically configured as illustrated. That is to say, the specific form of the distribution and integration of the respective devices is not limited to the illustrated one, and some of all thereof may be functionally or physically distributed or integrated in any unit depending on various loads, usage conditions, or the like.

Moreover, the respective processes described in the above embodiments described above may be suitably combined unless a conflict arises.

Furthermore, the “part (section, module, or unit)” described above may be replaced with a “means”, a “circuit”, or the like. For example, the acquisition part may be replaced with an acquisition means or an acquisition circuit.

According to the present disclosure in some embodiments, it is possible to easily control a formation of a film from multiple types of raw materials.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A control device, comprising:
an acquisition part configured to acquire data of saturation vapor pressure curves for plural types of raw materials used to form a film on a workpiece, and a predetermined saturation vapor pressure value set for the workpiece;
a selection part configured to select a raw material having a lowest saturation vapor pressure at a certain temperature, among the plural types of raw materials, based on the data of the saturation vapor pressure curves;
a calculation part configured to calculate a temperature corresponding to the predetermined saturation vapor pressure value for the selected raw material based on the data of the saturation vapor pressure curve for the selected raw material; and
a controller configured to control a temperature of the workpiece to the calculated temperature.

2. The device of claim 1, wherein the acquisition part is configured to acquire a first saturation vapor pressure value set for the workpiece, and a second saturation vapor pressure value that is higher than the first saturation vapor pressure value, the second saturation vapor pressure value being set for at least one of a chamber into which the workpiece is loaded and an exhaust pipe connected to the chamber,
the calculation part is configured to calculate a first temperature corresponding to the first saturation vapor pressure value and a second temperature corresponding to the second saturation vapor pressure value for the selected raw material, and
the controller is configured to control the temperature of the workpiece to the first temperature, and to control a temperature of the at least one of the chamber and the exhaust pipe to the second temperature.

3. The device of claim 1, wherein the acquisition part is configured to acquire a first saturation vapor pressure value set for the workpiece, and a third saturation vapor pressure value that is lower than the first saturation vapor pressure value, the third saturation vapor pressure value being set for a collection device configured to collect particles generated inside a chamber into which the workpiece is loaded,
the calculation part is configured to calculate a first temperature corresponding to the first saturation vapor pressure value and a third temperature corresponding to the third saturation vapor pressure value for the selected raw material, and
the controller is configured to control the temperature of the workpiece to the first temperature, and to control a temperature of the collection device to the third temperature.

4. The device of claim 1, wherein the plural types of raw materials include the raw material having the lowest saturation vapor pressure at the certain temperature, and at least one raw material having a saturation vapor pressure of at least 10 times higher than the lowest saturation vapor pressure at the certain temperature.

5. A film forming apparatus, comprising:
a chamber into which a workpiece is loaded;
a plurality of raw material sources configured to respectively store plural types of raw materials used to form a film on the workpiece;
a plurality of supply pipes through which the plural types of raw materials is supplied into the chamber, respectively;
an exhaust pipe connected to the chamber, and
the control device of claim 1.

6. A control method, comprising:
acquiring data of saturation vapor pressure curves for plural types of raw materials used to form a film on a workpiece, and a predetermined saturation vapor pressure value set for the workpiece;
selecting a raw material having a lowest saturation vapor pressure at a certain temperature, among the plural types of raw materials, based on the data of the saturation vapor pressure curves;
calculating a temperature corresponding to the predetermined saturation vapor pressure value for the selected raw material based on the data of the saturation vapor pressure curve for the selected raw material; and
controlling a temperature of the workpiece to the calculated temperature.

7. A film forming method, comprising:
the control method of claim 6; and
forming the film on the workpiece using the plural types of raw materials.

8. A non-transitory computer-readable recording medium storing a control program that causes a computer to perform a process, the process comprising:
acquiring data of saturation vapor pressure curves for plural types of raw materials used to form a film on a workpiece, and a predetermined saturation vapor pressure value set for the workpiece;
selecting a raw material having a lowest saturation vapor pressure at a certain temperature, among the plural types of raw materials, based on the data of the saturation vapor pressure curves;
calculating a temperature corresponding to the predetermined saturation vapor pressure value for the selected raw material based on the data of the saturation vapor pressure curve for the selected raw material; and
controlling a temperature of the workpiece to the calculated temperature.
